(19) United States
(12) Patent Application Publication
(10) Pub. No.: US 2022/0396863 A1
(43) Pub. Date: Dec. 15, 2022

(54) THIN FILM FOIL AND METHOD FOR MANUFACTURING THIN FILM FOIL

(71) Applicant: AMOGREENTECH CO., LTD., Gimpo-si, Gyeonggi-do (KR)

(72) Inventor: Sung Baek DAN, Hwaseong-si (KR)

(73) Assignee: AMOGREENTECH CO., LTD., Gimpo-si, Gyeonggi-do (KR)

(21) Appl. No.: 17/623,500

(22) PCT Filed: Jun. 26, 2020
(86) PCT No.: PCT/KR2020/008357

§ 371 Date: Dec. 28, 2021

(30) Foreign Application Priority Data
Jun. 28, 2019 (KR) 10-2019-0077864

(51) Int. Cl. C23C 14/00; C23C 14/16; C23C 14/20; C23C 14/34; C23C 14/02; H01M 4/04

(52) U.S. Cl. CPC C23C 14/0005; C23C 14/165; C23C 14/205; C23C 14/34; C23C 14/02; H01M 4/0426; H01M 2004/027

(57) ABSTRACT

The present invention provides a method for manufacturing a thin film foil, wherein a metal thin film layer is formed on a base substrate through a vacuum deposition process to form an ultra-thin film foil having a thickness of 5 μm or less, preferably 2 μm or less. The provided method for manufacturing a thin film foil comprises the steps of: preparing a base substrate having release properties; preparing a metal raw material; vacuum-depositing the metal raw material on the base substrate to form a metal layer on the base substrate; and separating the base substrate from the metal layer to form a thin film foil, wherein one of a BeCu alloy, a Cu—Ag—Cr ternary alloy, an Ag alloy, a CuMo alloy, and a CuFeP alloy is prepared as the metal raw material.

### TECHNICAL FIELD

The present disclosure relates to a thin film foil and a method for manufacturing the thin film foil, and more particularly, to a thin film foil used as a negative electrode material for a secondary battery and a method for manufacturing the thin film foil.

### BACKGROUND ART

Vehicles manufacturers have been developing various types of eco-friendly vehicles, such as a hybrid vehicle, a hydrogen vehicle, and an electric vehicle, as the demand for eco-friendly vehicles increases.

An electric vehicle is an eco-friendly vehicle that uses electricity as a power source and has a built-in battery to store electricity. An electric vehicle requires a large-capacity battery for stable long-distance operation. However, as the capacity of the battery increases, the volume and weight of the battery increase, so it is difficult to easily increase the capacity of the battery in a vehicle having a limited mounting space, and the charging time increases.

Accordingly, for the practical use of an electric vehicle, a battery that is lightweight, compact and has a shout charging time is essentially required. Since a battery is constructed by alternately stacking negative and positive electrode materials formed of a thin film foil (copper foil) coated with an active material, the thinner the thin film foil, the more active material may be coated, thereby minimizing the weight and volume of the battery.

Battery manufacturers are conducting research to minimize a thickness of the thin film foil in order to reduce the weight and size of the battery.

### SUMMARY OF INVENTION

### Technical Problem

The present disclosure has been proposed in consideration of the above circumstances, and an object of the present disclosure is to provide a thin film foil and a method for manufacturing a thin film foil in which a metal thin film layer is formed on a base substrate through a sputtering process to manufacture an ultra-thin film foil having a thickness of 5 μm or less, preferably 2 μm or less.

In addition, another object of the present disclosure is to provide a thin film foil and a method for manufacturing a thin film foil in which a metal layer with a multilayer structure is formed by sequentially sputtering a first metal raw material and a second metal raw material on a base substrate through a sputtering process.

In addition, another object of the present disclosure is to provide a thin film foil and a method for manufacturing a thin film foil in which a thin metal layer is formed through sputtering on a base substrate made of a material having excellent release properties to facilitate separation and transfer of the ultra-thin film foil.

### Solution to Problem

To achieve the object, a method for manufacturing a thin film foil according to an exemplary embodiment of the present disclosure includes: preparing a base substrate having release properties; preparing a metal raw material; forming a metal layer on the base substrate by vacuum-depositing the metal raw material on the base substrate; and separating the base substrate from the metal layer to form a thin film foil.

In the base substrate preparation step, one of a Teflon film, a Teflon-coated polyimide (PI), a polyimide (PI), a slip alloy-sputtered aluminum foil, a silicone-coated polyethylene terephthalate (PET) and a silicone film may be prepared as the base substrate.

In the metal raw material preparation step, one of a BeCu alloy, a Cu—Ag—Cr ternary alloy, an Ag alloy, a CuMo alloy, and a CuFeP alloy may be prepared as the metal raw material.

The metal raw material preparation step includes a first metal raw material preparation step, wherein in the first metal raw material preparation step, one of copper, a BeCu alloy, a Cu—Ag—Cr ternary alloy, an Ag alloy, a CuMo alloy, and a CuFeP alloy may be prepared as the first metal raw material.

The metal raw material preparation step further includes a second metal raw material preparation step, wherein in the second metal raw material preparation step, one of a nickel-copper alloy, a copper molybdenum alloy, and an Invar alloy may be prepared as a second metal raw material.

In the metal layer forming step, the first metal raw material and the second metal raw material may be alternately vacuum-deposited to form a metal layer having a plurality of layers.

In the metal layer forming step, a metal layer in which a copper layer and a nickel-copper alloy layer are repeatedly stacked may be formed.

In the metal layer forming step, a metal layer in which a copper layer and a copper molybdenum alloy layer are repeatedly stacked may be formed.

In the metal layer forming step, a metal layer in which a copper layer and an Invar alloy layer are repeatedly stacked may be formed.

In the step of forming a metal layer on the base substrate by vacuum-depositing the metal raw material on the base substrate, a metal layer may be formed on the base substrate by treating the base substrate with hydrophobic plasma and vacuum depositing the metal raw material on the hydrophobic plasma-treated base substrate.

In the step of forming a metal layer on the base substrate by vacuum-depositing the metal raw material on the base substrate, a metal layer may be formed on the base substrate by coating the base substrate with one of an acryl-based adhesive and a polyurethane-based adhesive, and vacuum-depositing the metal raw material on the adhesive.

In the step of forming a metal layer on the base substrate by vacuum-depositing the metal raw material on the base substrate, the metal layer may be formed to have a thickness of 5 μm or less.

A thin film foil may be formed of a metal layer having a thickness of 5 μm or less, wherein the metal layer includes at least one of a BeCu alloy, a Cu—Ag—Cr ternary alloy, an Ag alloy, a CuMo alloy, and a Cu and CuFeP alloy.

The metal layer may be formed in a single-layer or multi-layer structure.

### Advantageous Effects

According to the present disclosure, in a method for manufacturing a thin film foil, a metal thin film layer is formed by sputtering a metal raw material including at least one of a BeCu alloy, a Cu—Ag—Cr ternary alloy, an Ag alloy, a CuMo alloy, and a CuFeP alloy on a base substrate, such that an ultra-thin film foil having a thickness of 5 μm or less, preferably 2 μm or less may be manufactured.

In addition, in a method for manufacturing a thin film foil, a metal layer with a multilayer structure is formed by preparing copper as a first metal raw material, preparing one of a nickel-copper alloy, a copper molybdenum alloy, and an Invar alloy as a second metal raw material, and sequentially sputtering the first metal raw material and the second metal raw material on a base substrate through a sputtering process, such that an ultra-thin film foil having a thickness of 5 μm or less, preferably 2 μm or less may be manufactured.

Further, in a method for manufacturing a thin-film foil, one of a Teflon film, a Teflon-coated polyimide (PI), an aluminum foil in which a slip alloy is sputtered, and a silicon-coated polyethylene terephthalate (PET) is configured as the base substrate, and a thin metal layer is formed on a base substrate through sputtering, such that the ultra-thin film foil may be easily separated and transferred.

### BRIEF DESCRIPTION OF DRAWINGS

FIG. 1 is a flowchart illustrating a method for manufacturing a thin film foil according to a first embodiment of the present disclosure.

FIG. 2 is a flowchart illustrating a method for manufacturing a thin film foil according to a second embodiment of the present disclosure.

FIG. 3 is a configuration diagram illustrating a thin film foil manufactured by a method for manufacturing a thin film foil according to a second embodiment of the present disclosure.

FIG. 4 is a flowchart illustrating a method for manufacturing a thin film foil according to a third embodiment of the present disclosure.

FIG. 5 is a flowchart illustrating a method for manufacturing a thin film foil according to a fourth embodiment of the present disclosure.

FIG. 6 is a flowchart illustrating a method for manufacturing a thin film foil according to a fifth embodiment of the present disclosure.

FIG. 7 is a configuration diagram illustrating a thin film foil manufactured by a method for manufacturing a thin film foil according to the fifth embodiment of the present disclosure.

FIG. 8 is an FIB fracture SEM photograph, enlarged at a magnification of 15,000 times, of a BeCu thin film foil manufactured by a method for manufacturing a thin film foil according to the first embodiment of the present disclosure.

FIG. 9 is an FIB fracture SEM photograph, enlarged at a magnification of 50,000 times, of a BeCu thin film foil manufactured by a method for manufacturing a thin film foil according to the first embodiment of the present disclosure.

FIG. 10 is an FIB fracture SEM photograph, enlarged at a magnification of 15,000 times, of a Cu thin film foil manufactured by a method for manufacturing a thin film foil according to the first embodiment of the present disclosure.

FIG. 11 is an FIB fracture SEM photograph, enlarged at a magnification of 50,000 times, of a Cu thin film foil manufactured by a method for manufacturing a thin film foil according to the first embodiment of the present disclosure.

FIG. 12 is an FIB fracture SEM photograph, enlarged at a magnification of 15,000 times, of a Cu—CuMo multilayer thin film foil manufactured by a method for manufacturing a thin film foil according to the second embodiment of the present disclosure.

FIG. 13 is an FIB fracture SEM photograph, enlarged at a magnification of 150,000 times, of a Cu—CuMo multilayer thin film foil manufactured by a method for manufacturing a thin film foil according to the second embodiment of the present disclosure.

### DESCRIPTION OF EMBODIMENTS

Hereinafter, in order to describe in detail enough that a person of ordinary skill in the art to which the present disclosure pertains can easily implement the technical idea of the present disclosure, the most preferred embodiment of the present disclosure will be described with reference to the accompanying drawings. First, it is to be noted that in giving reference numerals to components of each of the accompanying drawings, the same components will be denoted by the same reference numerals even though they are illustrated in different drawings. Further, in describing exemplary embodiments of the present disclosure, if it is determined that a detailed description of a related known configuration or function may obscure the gist of the present disclosure, the detailed description thereof will be omitted.

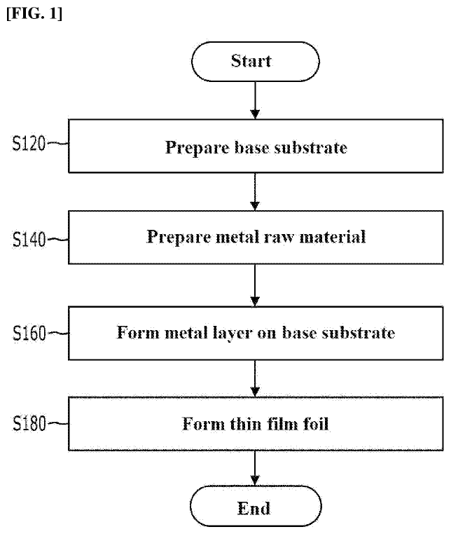

Referring to FIG. 1, a method for manufacturing a thin film foil according to a first embodiment of the present disclosure includes a base substrate preparation step S120, a metal raw material preparation step S140, a metal layer forming step S160, and a thin film foil forming step S180.

In the base substrate preparation step S120, a base substrate having release properties is prepared. In the base substrate preparation step S120, one of a Teflon film, Teflon-coated polyimide (PI), a slip alloy-sputtered aluminum foil, and a silicone-coated polyethylene terephthalate (PET) having excellent release properties is prepared as a base substrate.

In the metal raw material preparation step S140, a copper alloy is prepared as a sputtering raw material. In the metal raw material preparation step S140, one of a BeCu alloy, a Cu—Ag—Cr ternary alloy, a CuMo alloy, and a CuFeP alloy is prepared as a metal raw material. In the metal raw material preparation step S140, preparing a copper alloy as a sputtering raw material is to select a material with high rigidity.

Alternatively, in the metal raw material preparation step S140, one of an Ag alloy and an Al alloy may be prepared as a metal raw material. For example, AgPd may be prepared as Ag alloy, and duralumin may be prepared as an Al alloy. In the metal raw material preparation step S140, preparing one of an Ag alloy and an Al alloy as a metal raw material is to select a material having high conductivity and high rigidity.

In the metal layer forming step S160, an ultra-thin metal layer is formed on the base substrate through vacuum deposition. There are various methods for vacuum deposition, and the first embodiment is performed by selecting a sputtering process, which is one of the vacuum deposition methods.

In the metal layer forming step S160, an ultra-thin metal layer is formed on the base substrate through a sputtering process. In the metal layer forming step S160, an ultra-thin metal layer is formed on the base substrate by sputtering a metal raw material. In this case, in the metal layer forming step S160, a metal layer having a thickness of 5 μm, preferably 2 μm or less, is formed on the base substrate through a sputtering process.

In the thin film foil forming step S180, the base substrate having a release properties is separated from the metal layer to form an ultra-thin film foil. In this case, in the thin film foil forming step S180, an ultra-thin film foil having a thickness of 5 μm or less, preferably 2 μm or less is prepared.

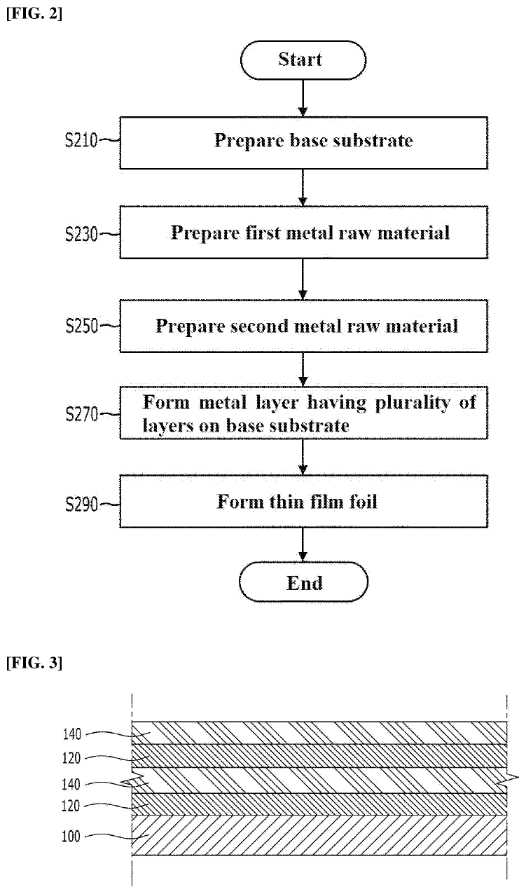

Referring to FIG. 2, a method for manufacturing a the thin film foil according to a second embodiment of the present disclosure includes a base substrate preparation step S210, a first metal raw material preparation step S230, a second metal raw material preparation step S250, a metal layer formation step S270, and a thin film foil formation step S290.

In the base substrate preparation step S210, a base substrate having release properties is prepared. In the base substrate preparation step S210, one of a Teflon film having excellent release properties, Teflon-coated polyimide (PI), a slip alloy-sputtered aluminum foil, and a silicone-coated polyethylene terephthalate (PET) is prepared as a base substrate.

In the first metal raw material preparation step S230, copper is prepared as the first metal raw material.

Alternatively, in the first metal raw material preparation step S230, one of a BeCu alloy, a Cu—Ag—Cr ternary alloy, an Ag alloy, a CuMo alloy, and a CuFeP alloy is prepared as the first metal raw material.

In the second metal raw material preparation step S250, a copper alloy is prepared as a second metal raw material. In the second metal raw material preparation step S250, one of a nickel-copper alloy, a copper molybdenum alloy, and an Invar alloy is prepared as a second metal raw material.

In the metal layer forming step S270, the first metal raw material and the second metal raw material are vacuum-deposited to form a metal layer on the base substrate. There are various methods for vacuum deposition, and the second embodiment is performed by selecting a sputtering process, which is one of the vacuum deposition methods.

In the metal layer forming step S270, the first metal raw material and the second metal raw material are sputtered to form a metal layer on the base substrate. In the metal layer forming step S270, the first metal raw material and the second metal raw material are sequentially sputtered on the base substrate.

Referring to FIG. 3, in the metal layer forming step S270, the first metal raw material 120 and the second metal raw material 140 are sequentially stacked on the base substrate 100 to form a metal layer having a plurality of layers.

In the metal layer forming step S270, as an example, a metal layer having a four-layer structure in which a copper layer, a nickel-copper (NiCu) alloy layer, a copper layer, and a nickel-copper alloy layer are sequentially stacked is formed. The strength of the thin film foil may be increased by applying a four-layer structure in which a copper layer and a nickel-copper alloy layer are sequentially stacked.

In the metal layer forming step S270, as an example, a metal layer having a four-layer structure in which a copper layer, a copper molybdenum (CuMo) alloy layer, a copper layer, and a copper molybdenum alloy layer are sequentially stacked is formed. The strength of the thin film foil may be increased by applying a four-layer structure in which a copper layer, a copper molybdenum (CuMo) alloy layer, a copper layer, and a copper molybdenum alloy layer are sequentially stacked.

In the metal layer forming step S270, as an example, a metal layer having a four-layer structure in which a copper layer, an Invar alloy layer, a copper layer, and an Invar alloy layer are sequentially stacked is formed. The strength of the thin film foil may be increased by applying a four-layer structure in which a copper layer, an Invar alloy layer, a copper layer, and an Invar alloy layer are sequentially stacked.

In the thin film foil forming step S290, the base substrate having release properties is separated from the metal layer to form an ultra-thin film foil. In this case, in the thin film foil forming step S290, an ultra-thin film foil having a thickness of 5 μm or less, preferably 2 μm or less is prepared.

An ultra-thin film foil having a thickness of 5 μm or less, preferably 2 μm or less, is thin and easy to tear if the strength is low. Therefore, the strength may be increased by applying the above-described copper alloy layer or multi-layer structure rather than a single copper layer structure.

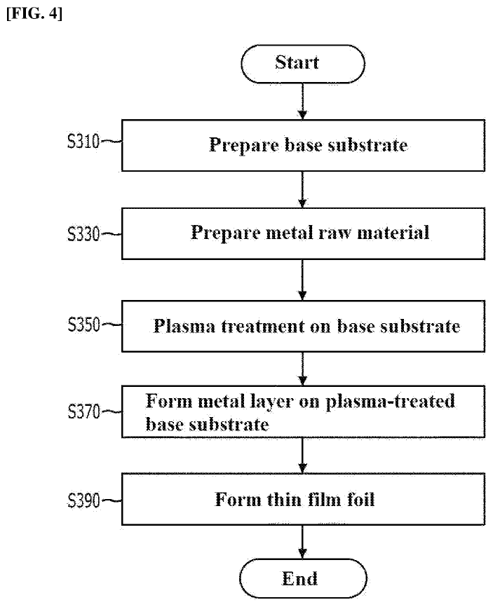

Referring to FIG. 4, a method for manufacturing a thin film foil according to a third embodiment of the present disclosure includes a base substrate preparation step S310, a metal raw material preparation step S330, a plasma treatment step S350, a metal layer forming step S370, and a thin film foil forming step S390.

In the base substrate preparation step S310, one of polyimide (PI), a silicone film, and an aluminum foil is prepared as a base substrate.

In the metal raw material preparation step S330, a copper alloy is prepared as a sputtering raw material. In the metal raw material preparation step S330, one of a BeCu alloy, a Cu—Ag—Cr ternary alloy, a CuMo alloy, and a CuFeP alloy is prepared as a metal raw material. In the metal raw material preparation step S140, preparing a copper alloy as a sputtering raw material is to select a material with high rigidity.

Alternatively, in the metal raw material preparation step S330, one of an Ag alloy and an Al alloy may be prepared as a metal raw material. For example, AgPd may be prepared as an Ag alloy, and duralumin may be prepared as an Al alloy. In the metal raw material preparation step S330, preparing one of an Ag alloy and an Al alloy as a metal raw material is to select a material having high conductivity and high rigidity.

In the plasma treatment step S350, release properties are imparted to the base substrate. In the plasma treatment step S350, hydrophobic plasma treatment is performed to impart release properties to the base substrate having weak releasability. In the plasma treatment step S350, a hydrophobic material such as CF4 is used to impart hydrophobic properties to the base material so that the base material has release properties. When a hydrophobic plasma treatment is performed on a base substrate such as polyimide (PI), a silicon film, and an aluminum foil, and a metal layer is formed through a sputtering process, the release properties are improved.

In the metal layer forming step S370, an ultra-thin metal layer is formed on the base substrate through vacuum deposition. There are various methods for vacuum deposition, and the third embodiment is performed by selecting a sputtering process, which is one of the vacuum deposition methods.

In the metal layer forming step S370, an ultra-thin metal layer is formed on the base substrate through a sputtering process. In the metal layer forming step S370, an ultra-thin metal layer is formed on the base substrate by stuffing a metal raw material on the hydrophobic plasma-treated base substrate. In this case, in the metal layer forming step S370, a metal layer having a thickness of 5 μm, preferably 2 μm or less, is formed on the base substrate through a sputtering process.

In the thin film foil forming step S390, the base substrate having release properties by plasma treatment is separated from the metal layer to form an ultra-thin film foil. In this case, in the thin film foil forming step S390, an ultra-thin film foil having a thickness of 5 μm or less, preferably 2 μm or less is prepared.

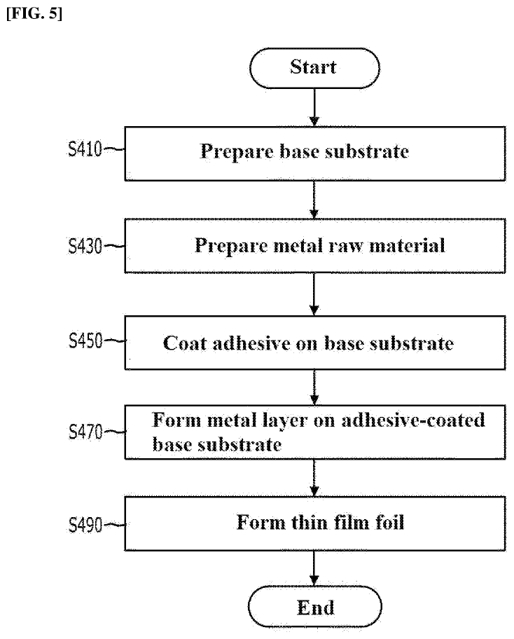

Referring to FIG. 5, a method for manufacturing a thin film foil according to a fourth embodiment of the present disclosure includes a base substrate preparation step S410, a metal raw material preparation step S430, an adhesive coating step S450, a metal layer forming step S470, and a thin film foil forming step S490.

In the base substrate preparation step S410, one of polyimide (PI), a silicone film, and an aluminum foil is prepared as a base substrate.

In the metal raw material preparation step S430, a copper alloy is prepared as a sputtering raw material. In the metal raw material preparation step S430, one of a BeCu alloy, a Cu—Ag—Cr ternary alloy, a CuMo alloy, and a CuFeP alloy is prepared as a metal raw material. In the metal raw material preparation step S430, preparing a copper alloy as a sputtering raw material is to select a material with high rigidity.

Alternatively, in the metal raw material preparation step S430, one of an Ag alloy and an Al alloy may be prepared as a metal raw material. For example, AgPd may be prepared as an Ag alloy, and duralumin may be prepared as an Al alloy. In the metal raw material preparation step S430, preparing one of an Ag alloy and an Al alloy as a metal raw material is to select a material having high conductivity and high rigidity.

In the adhesive coating step S450, release properties are imparted to the base substrate. In the adhesive coating step S450, the adhesive is coated to impart release properties to the base substrate having weak releasability. In the adhesive coating step S450, one of an acrylic-based adhesive and a polyurethane-based adhesive is coated on the base substrate. Releasability is improved when an adhesive is coated on a base substrate having weak releasability and a metal layer is formed through a sputtering process.

In the metal layer forming step S470, an ultra-thin metal layer is formed on the base substrate through vacuum deposition. There are various methods for vacuum deposition, and the fourth embodiment is performed by selecting a sputtering process, which is one of the vacuum deposition methods.

In the metal layer forming step S470, an ultra-thin metal layer is formed on the base substrate through a sputtering process. In the metal layer forming step S470, a metal raw material is sputtered on the adhesive coated on the base substrate to form an ultra-thin metal layer on the adhesive of the base substrate. In this case, in the metal layer forming step S470, a metal layer having a thickness of 5 μm, preferably 2 μm or less, is formed on the adhesive of the base substrate through a sputtering process.

In the thin film foil forming step S490, an adhesive is coated to separate the base substrate having release properties from the metal layer to form an ultra-thin film foil. In this case, in the thin film foil forming step S490, an ultra-thin film foil having a thickness of 5 μm or less, preferably 2 μm or less is prepared.

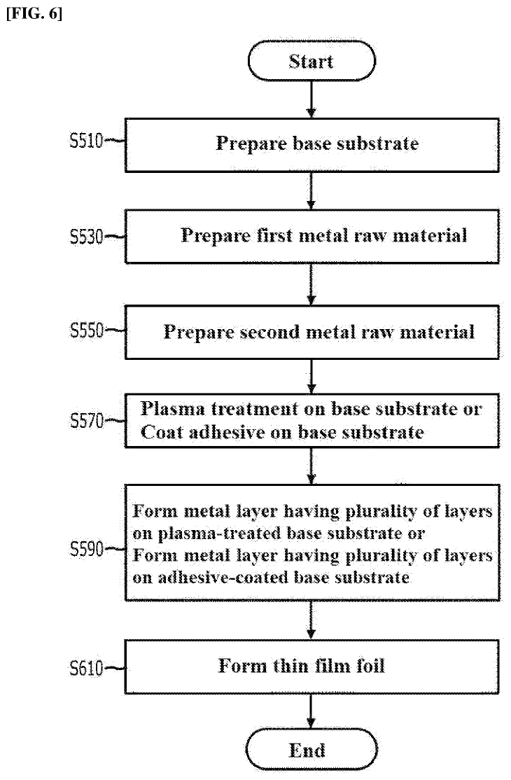

Referring to FIG. 6, a method for manufacturing the thin film foil according to a fifth embodiment of the present disclosure includes a base substrate preparation step S510, a first metal raw material preparation step S530, a second metal raw material preparation step S550, a plasma treatment step on the base substrate or an adhesive coating step on the base substrate S570, a metal layer forming step S590, and a thin film foil forming step S610.

In the base substrate preparation step S510, one of polyimide (PI), a silicone film, and an aluminum foil is prepared as a base substrate.

In the first metal raw material preparation step S530, copper is prepared as the first metal raw material.

Alternatively, in the first metal raw material preparation step S530, one of a BeCu alloy, a Cu—Ag—Cr ternary alloy, an Ag alloy, a CuMo alloy, and a CuFeP alloy is prepared as the first metal raw material.

In the second metal raw material preparation step S550, a copper alloy is prepared as a second metal raw material. In the second metal raw material preparation step S550, one of a nickel-copper alloy, a copper molybdenum alloy, and an Invar alloy is prepared as a second metal raw material.

In the plasma treatment step on the base substrate or the adhesive coating step on the base substrate S570, a hydrophobic plasma treatment is performed on the base substrate to impart release properties, or an adhesive is coated on the base substrate to impart release properties.

In the metal layer forming step S590, the first metal raw material and the second metal raw material are vacuum-deposited to form a metal layer on the base substrate. There are various methods for vacuum deposition, and the fifth embodiment is performed by selecting a sputtering process, which is one of the vacuum deposition methods.

In the metal layer forming step S590, a metal layer is formed on the base substrate by sputtering the first metal raw material and the second metal raw material on the hydrophobic plasma-treated base substrate or the adhesive-coated base substrate. In the metal layer forming step S590, the first metal raw material and the second metal raw material are sequentially sputtered on the hydrophobic plasma-treated base substrate or the adhesive-coated base substrate.

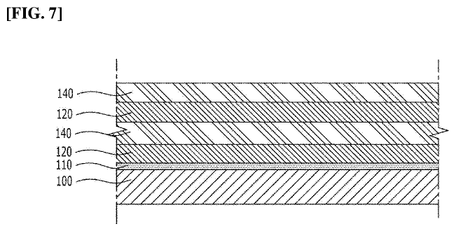

Referring to FIGS. 6 and 7, in the metal layer forming step S590, the first metal raw material 120 and the second metal raw material 140 are sequentially stacked on the hydrophobic plasma-treated or adhesive 110-coated base substrate 100 to form a metal layer having a plurality of layers.

As an example, the metal layer has a four-layer structure in which a copper layer, a nickel-copper (NiCu) alloy layer, a copper layer, and a nickel-copper alloy layer are sequentially stacked.

As an example, the metal layer has a four-layer structure in which a copper layer, a copper molybdenum (CuMo) alloy layer, a copper layer, and a copper molybdenum alloy layer are sequentially stacked.

As an example, the metal layer has a four-layer structure in which a copper layer, an Invar alloy layer, a copper layer, and an Invar alloy layer are sequentially stacked.

Although it has been described that the metal layer has a four-layer structure as an example, a six-layer structure, an eight-layer structure and a ten-layer structure in which the first metal raw material 120 and the second raw material metal 140 are sequentially stacked are also possible, if necessary.

In the thin film foil forming step S610, the hydrophobic plasma treatment or the adhesive 110-coated base substrate is separated from the metal layer to form an ultra-thin film foil. In this case, in the thin film foil forming step S290, an ultra-thin film foil having a thickness of 5 μm or less, preferably 2 μm or less is prepared.

The thin film foil manufactured by the above-described method is formed of a metal layer having a thickness of 5 μm or less. The metal layer is formed in a single-layer or multi-layer structure.

The metal layer with a single-layer structure may be formed of at least one of a BeCu alloy, a Cu—Ag—Cr ternary alloy, an Ag alloy, a CuMo alloy, and a CuFeP alloy.

The metal layer with a multi-layer structure may have a structure in which a copper layer and a nickel-copper alloy layer are repeatedly stacked. Alternatively, the metal layer with a multi-layer structure may have a structure in which a copper layer and a copper molybdenum alloy layer are repeatedly stacked. Alternatively, the metal layer with a multi-layer structure may have a structure in which a copper layer and an Invar alloy layer are repeatedly stacked. Alternatively, the metal layer with a multi-layer structure may have a structure in which a copper alloy and a copper molybdenum alloy layer are repeatedly stacked.

The above-described first to fifth embodiments may be mixed and applied, if necessary.

Hereinafter, FIB fracture analysis of the thin film foil sample manufactured by the method for manufacturing a thin film foil according to an embodiment of the present disclosure was performed.

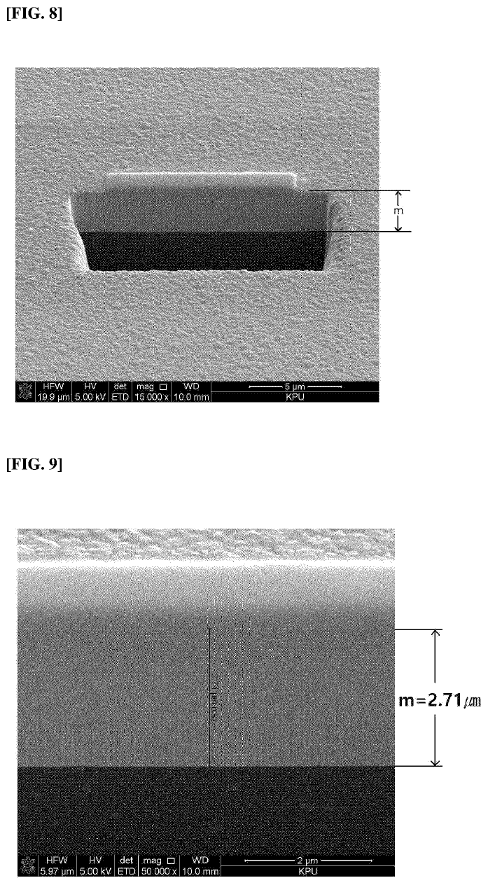

FIG. 8 is an FIB fracture SEM photograph, enlarged at a magnification of 15,000 times, of the BeCu thin film foil manufactured by a method for manufacturing the thin film foil according to the first embodiment of the present disclosure. FIG. 9 is an FIB fracture SEM photograph, enlarged at a magnification of 50,000 times, of a BeCu thin film foil manufactured by a method for manufacturing a thin film foil according to the first embodiment of the present disclosure

It was confirmed from FIGS. 8 and 9 that defects were generated by irradiating ions such as Ge to a BeCu thin film foil sample manufactured by a method for manufacturing a thin film foil according to the first embodiment, and as a result of checking the cross section, the thickness (m) of the cross section was 2.71 μm.

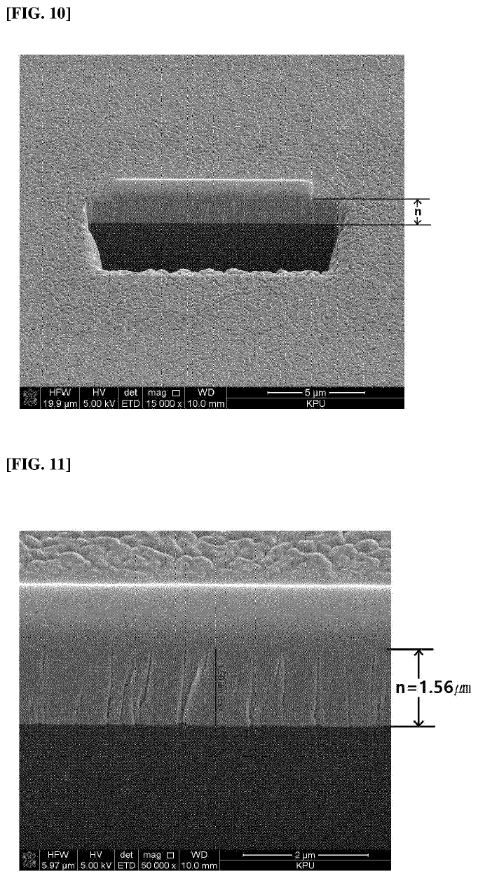

FIG. 10 is an FIB fracture SEM photograph, enlarged at a magnification of 15,000 times, of a Cu thin film foil manufactured by a method for manufacturing a thin film foil according to the first embodiment of the present disclosure. FIG. 11 is an FIB fracture SEM photograph, enlarged at a magnification of 50,000 times, of a Cu thin film foil manufactured by a method for manufacturing a thin film foil according to the first embodiment of the present disclosure

It was confirmed from FIGS. 10 and 11 that defects were generated by irradiating ions such as Ge⁺ to a Cu thin film foil sample manufactured by a method for manufacturing a thin film foil according to the first embodiment, and as a result of checking the cross section of the Cu thin film foil sample, the thickness (m) of the cross section was 1.56 μm.

According to the experimental results of FIGS. 8 to 11, it was observed that the FIB fractured cross section of the BeCu thin film foil sample was clean, while the FIB fractured cross section of the Cu thin film foil sample had some longitudinal cracks during a fracture process. This is confirmed to have occurred because the Cu-only thin film foil has lower strength than the Cu alloy thin film foil. Therefore, it is possible to increase the strength by using the Cu alloy thin film foil rather than Cu alone.

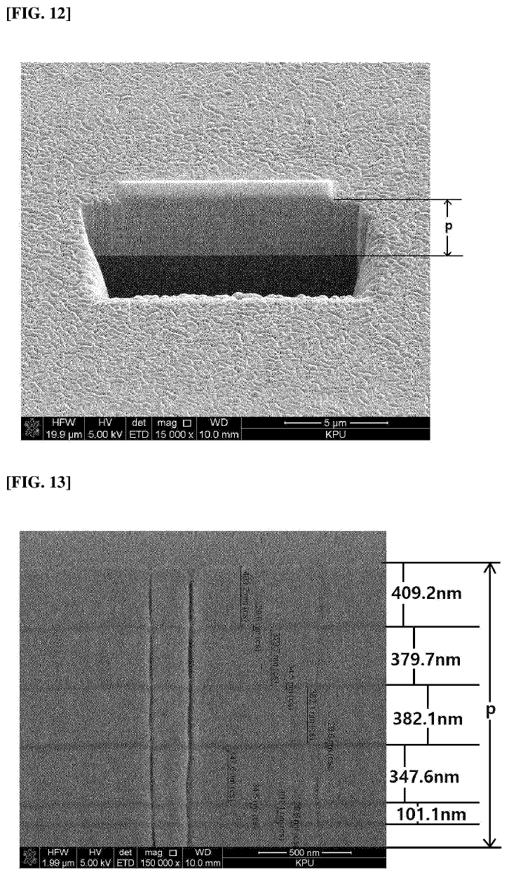

FIG. 12 is an FIB fracture SEM photograph, enlarged at a magnification of 15,000 times, of a Cu—CuMo multilayer thin film foil manufactured by a method for manufacturing a thin film foil according to the second embodiment of the present disclosure. FIG. 13 is an FIB fracture SEM photograph, enlarged at a magnification of 150,000 times, of a Cu—CuMo multilayer thin film foil manufactured by a method for manufacturing a thin film foil according to the second embodiment of the present disclosure.

It was confirmed from FIGS. 12 and 13 that defects were generated by irradiating ions such as Ge⁺ to a Cu—CuMo multilayer thin film foil sample manufactured by a method for manufacturing a thin film foil according to the second embodiment, and as a result of checking the cross section of the Cu—CuMo multilayer thin film foil sample, the thickness (p) of the cross section was 5 μm or less.

From the above experimental results, it can be confirmed that an ultra-thin film foil having a thickness of 5 μm or less, preferably 2 μm or less, may be manufactured by forming a metal thin film layer with a single-layer or multi-layer structure on a base substrate through a sputtering process.

Although the preferred embodiment according to the present disclosure has been described above, it is understood that various modifications and variations are possible, and various modifications and modifications can be made by those of ordinary skill in the art without departing from the scope of the claims of the present disclosure.

1. A method for manufacturing a thin film foil, the method comprising the steps of:
preparing a base substrate having release properties;
preparing a metal raw material;
forming a metal layer on the base substrate by vacuum-depositing the metal raw material on the base substrate; and
separating the base substrate from the metal layer to form a thin film foil

2. The method of claim 1, wherein in the base substrate preparation step, one of a Teflon film, a Teflon-coated polyimide (PI), a polyimide (PI), a slip alloy-sputtered aluminum foil, a silicone-coated polyethylene terephthalate (PET) and a silicone film is prepared as the base substrate.

3. The method of claim 1, wherein in the metal raw material preparation step, one of a BeCu alloy, a Cu—Ag—Cr ternary alloy, an Ag alloy, a CuMo alloy, and a CuFeP alloy is prepared as the metal raw material.

4. The method of claim 1, wherein the metal raw material preparation step includes a first metal raw material preparation step,
wherein in the first metal raw material preparation step, one of copper, a BeCu alloy, a Cu—Ag—Cr ternary alloy, an Ag alloy, a CuMo alloy, and a CuFeP alloy is prepared as the first metal raw material.

5. The method of claim 4, wherein the metal raw material preparation step further includes a second metal raw material preparation step,
wherein in the second metal raw material preparation step, one of a nickel-copper alloy, a copper molybdenum alloy, and an Invar alloy is prepared as a second metal raw material.

6. The method of claim 5, wherein in the metal layer forming step, the first metal raw material and the second metal raw material are alternately vacuum-deposited to form a metal layer having a plurality of layers.

7. The method of claim 6, wherein in the metal layer forming step, a metal layer in which a copper layer and a nickel-copper alloy layer are repeatedly stacked is formed.

8. The method of claim 6, wherein in the metal layer forming step, a metal layer in which a copper layer and a copper molybdenum alloy layer are repeatedly stacked is formed.

9. The method of claim 6, wherein in the metal layer forming step, a metal layer in which a copper layer and an Invar alloy layer are repeatedly stacked is formed.

10. The method of claim 1, wherein in the step of forming a metal layer on the base substrate by vacuum-depositing the metal raw material on the base substrate, a metal layer is formed on the base substrate by treating the base substrate with hydrophobic plasma and vacuum depositing the metal raw material on the hydrophobic plasma-treated base substrate.

11. The method of claim 1, wherein in the step of forming a metal layer on the base substrate by vacuum-depositing the metal raw material on the base substrate, a metal layer is formed on the base substrate by coating the base substrate with one of an acryl-based adhesive and a polyurethane-based adhesive, and vacuum-depositing the metal raw material on the adhesive.

12. The method of claim 1, wherein in the step of forming a metal layer on the base substrate by vacuum-depositing the metal raw material on the base substrate, the metal layer is formed to have a thickness of 5 μm or less.

13. A thin film foil formed of a metal layer having a thickness of 5 μm or less,
wherein the metal layer includes at least one of a BeCu alloy, a Cu—Ag—Cr ternary alloy, an Ag alloy, a CuMo alloy, and a Cu and CuFeP alloy.

14. The thin film foil of claim 13, wherein the metal layer is formed in a single-layer or multi-layer structure.
